(19) United States
(12) Patent Application Publication
(10) Pub. No.: US 2012/0148942 A1
(43) Pub. Date: Jun. 14, 2012

(54) DIAGONAL INTERCONNECT FOR IMPROVED PROCESS MARGIN WITH OFF-AXIS ILLUMINATION

(76) Inventor: James Walter Blatchford, Richardson, TX (US)

(21) Appl. No.: 12/966,252

(22) Filed: Dec. 13, 2010

(51) Int. Cl. G03F 1/00; G03F 7/00

(52) U.S. Cl. 430/5; 430/322; 430/319

(57) ABSTRACT

Mask or reticle methods and structures having pattern feature segments formed at oblique angles to each other. When illuminated using off-axis illumination techniques, a mask or reticle according to the present teachings can result in a more accurately reproduced feature within a photosensitive layer.

### TECHNICAL FIELD

The present teachings relate to the field of integrated circuits, and more specifically to semiconductor device structures and their method of formation.

### BACKGROUND

Conventional optical projection lithography has been the standard silicon patterning technology in semiconductor manufacturing processes, e.g., in the fabrication of integrated circuits (ICs). During lithographic projection, a mask that includes a semiconductor circuit layout pattern can be imaged onto a substrate that is at least partially covered by a photosensitive layer, for example, a layer of photoresist (i.e., “resist”). Layouts used to create such masks are typically generated using computer-aided design (CAD) programs, sometimes called electronic design automation (EDA). For example, most CAD programs follow a set of predetermined design rules to create functional masks.

One goal in IC fabrication is to faithfully reproduce the original circuit design or layout on a semiconductor wafer or wafer section, such as a silicon wafer or wafer section such as a semiconductor die, using the designed mask. Another goal is to use as much of the wafer real estate as possible. As the size of an IC is reduced and its density increases, however, the critical dimension (“CD”, for purposes of this disclosure, the smallest physical dimension printable on a wafer below which the feature size is not reliably reproducible) of its corresponding mask approaches the resolution limit of the optical exposure tool. For example, transistor matching requirements for advanced technology nodes such as less than 1.0 μm, require exquisite CD control, beyond the capability of current lithography and etch tools and processes. An important component of variation is matching between gates in the interior of an array of active gates, e.g., over the same active region, and those on the end of the array. For example, for the 45 nm technology node, the printed interior gates may vary from their designed size by a value of X, while the printed end gates might vary from their designed size by a value of 2 to 3 times X.

Off-axis illumination (OAI) is a resolution enhancement technology (RET) which has been used to improve structure patterning at more advanced technology nodes to achieve tight pitch requirements. OAI is a technique which uses a type of light blocking mask, referred to as an OAI element, to shape a light source. The light source shaped by the OAI element is then used to illuminate a patterned photomask. After being patterned by the photomask, the light source illuminates and patterns the photosensitive layer with the photomask pattern. Then, the patterned photosensitive layer can be used as a pattern to etch an underlying layer.

Off-axis illumination elements can take various forms. A monopole element can include a circular light blocking portion and a single shaped opening located at an edge of the light blocking portion. A dipole element can include a circular light blocking portion and two shaped openings, for example, located at 0° and 180° toward an edge of the circular light blocking portion, and a quadrupole element can include a circular light blocking portion and four shaped openings located at 0°, 90°, 180°, and 270° toward an edge of the circular light blocking portion.

During use of the dipole element, the illumination source can be aligned with a center of the dipole element, the photosensitive layer can be illuminated through the dipole element and the photomask, the dipole element can rotated 90°, then the photosensitive layer is illuminated again.

The OAI element can be aligned with an axis of the features being patterned. Patterned features typically include elongated structures, such as a plurality of elongated, parallel lines which can be transistor gates formed as part of a gate array.

### SUMMARY

The following presents a simplified summary in order to provide a basic understanding of some aspects of one or more embodiments of the present teachings. This summary is not an extensive overview, nor is it intended to identify key or critical elements of the present teachings nor to delineate the scope of the disclosure. Rather, its primary purpose is merely to present one or more concepts in simplified form as a prelude to the detailed description presented later.

An embodiment of the present teachings can include a method for imaging a pattern onto a photosensitive layer. The method can include providing an emitted light from a light source, passing at least a portion of the emitted light through an off-axis illumination (OAI) element to shape the emitted light, and passing at least a portion of the shaped emitted light through a patterned mask comprising at least one continuous patterned line to pattern the emitted light. The continuous patterned line can include a first line segment aligned along a first axis of orientation, a second line segment aligned along a second axis of orientation which is generally parallel to the first axis of orientation, and a third line segment aligned along a third axis of orientation which is oriented at an oblique angle relative to the first axis of orientation and the second axis of orientation. The third line segment can connect the first line segment to the second line segment. Additionally, the method can further include illuminating a photosensitive layer with the patterned emitted light.

Another embodiment of the present teachings can include a mask for imaging a photosensitive layer. The mask can include a continuous patterned line having a first line segment aligned along a first axis of orientation, a second line segment aligned along a second axis of orientation which is generally parallel to the first axis of orientation, and a third line segment aligned along a third axis of orientation which is oriented at an oblique angle relative to the first axis of orientation and the second axis of orientation, wherein the third line segment connects the first line segment to the second line segment.

Yet another embodiment of the present teaching can include a method for imaging a pattern during the formation of a semiconductor device. The method can include forming a photosensitive layer over a semiconductor wafer or semiconductor wafer section, then providing an emitted light from a light source. At least a portion of the emitted light passes through an off-axis illumination (OAI) element to shape the emitted light, and at least a portion of the shaped emitted light is passed through a patterned mask comprising at least one continuous patterned line to pattern the shaped emitted light. The continuous patterned line can include a first line segment aligned along a first axis of orientation, a second line segment aligned along a second axis of orientation which is generally parallel to the first axis of orientation, and a third line segment aligned along a third axis of orientation which is oriented at an oblique angle relative to the first axis of orientation and the second axis of orientation. The third line segment can connect the first line segment to the second line segment. Additionally, the method can further include illuminating the photosensitive layer with the patterned emitted light.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1 is a plan view of a portion of a photomask having pattern features with 90° angles which can be used to form semiconductor device features;

FIG. 2 is a plan view of a portion of a photomask having pattern features with angles which vary from the 90° angles of the FIG. 1 pattern features;

FIG. 3 is a depiction of the angles of the FIG. 2 pattern features; and

FIG. 4 is a perspective view of a system in accordance with an embodiment of the present teachings which includes a photomask having pattern features with angles which vary from the 90° angles of FIG. 1.

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Reference will now be made in detail to the exemplary embodiments of the present teachings, an example of which is illustrated in the accompanying drawings. Wherever possible, the same reference numbers will be used throughout the drawings to refer to the same or like parts.

As used herein, the term “design” refers to geometric shapes (i.e., a plurality of polygons) for a mask layout (i.e., a schematic used to make a semiconductor device) that correspond to mask features formed on a mask or set of masks, and/or features formed in/on the substrate. The mask layout can be used to form a mask or mask set that includes mask features (polygons) that can be used to endow an incoming beam with a patterned cross-section, corresponding to a target pattern that is to be created in/on a target portion of a substrate.

The mask feature can be used to pattern a feature on a substrate. Examples of a semiconductor feature can include a gate, a gate bus, a well, an isolation structure, an interconnect line, a space, a contact hole, a pillar, a resistor, a ghost feature, a dummy feature, or any other element of a semiconductor device or other device as will be understood by one of ordinary skill in the art. In various embodiments, a mask feature can include a resolution enhancement technique (RET) design, such as a phase shifter, a sub-resolution assist feature (SRAF), or another optical proximity correction (OPC) technique that assists in forming a feature on the substrate. In an exemplary embodiment, a mask feature can include one or more printable-assist features laid out on a mask design. In various embodiments, multiple mask features can be used to form structures on the substrate. The multiple structures, when finally formed, can combine to form a desired semiconductor feature.

As used herein unless otherwise specified, the term “printable-assist feature” or “dummy feature” refers to an assist feature laid out from IC mask design and used to improve the critical dimension control when forming semiconductor devices by removing or minimizing the differences in optical proximity correction (OPC) and responses to process variations. Unlike ghost features known in the prior art, the “printable-assist features” can be laid out adjacent to or extended from a semiconductor feature and can remain on the produced final substrate/wafer, while ghost features can be initially formed on a substrate but later removed as described in the related U.S. patent application Ser. No. 11/269,633, entitled “Gate Critical Dimension Variation by Use of Ghost Features,” and Ser. No. 11/482,041, entitled “Two-Print-Two-Etch Method for Enhancement of CD Control Using Ghost Poly,” which are hereby incorporated by references in their entirety.

For example, a “printable-assist feature” can be a “printable-gate-assist feature” formed at the end of a gate array so that the environment at the end of the gate array is similar to the environment in the interior of the gate array. That is, the printable-gate-assist feature can be drawn adjacent to, e.g., a polysilicon gate (i.e., “polygate”). In this case, printable-assist features can be used to reduce the critical dimension variation, such as, for example, for gates at the end of a gate array. in another example, the “printable-assist feature” can be a “printable-gate-extension feature” formed to lengthen gate extensions to match a length of a longer adjacent transistor gate feature.

In various embodiments, printable-assist features can be made of the same material as the other features concurrently formed on a substrate or a wafer. In the case of an array of gates made from a layer of polysilicon, for example, the printable-gate-assist feature can be formed from the same layer of polysilicon. In other instances, however, where the layer is made of another material, such as a metal, a semiconductor, or an insulator, the printable-gate-assist feature or the printable-gate-extension feature can be made of that material.

The disclosed strategic placement of the printable assist features can improve CD control, e.g., for transistor gates. For example, design rules have can be established to layout gates in a grid fashion, so that the control of internal gates on active regions can have the same control as external gates at the edge of active. In addition, printable gate-assist feature can enable gates at the edge of cell libraries to have the same control as internal density patterned gates. In an exemplary embodiment, the printable-assist features can be placed (e.g., laid out in the mask layout) on a grid layout over shallow trench isolation (e.g., field oxide) to provide good optical diffraction support to adjacent functional gates on active silicon.

In various embodiments, the design layout can include, for example, placing printable-assist features over a defined pitch range determined by simulation, defining line end extensions that mimic gate line end extensions, and attaching extensions to existing gates to support longer neighboring gates. In various embodiments, the disclosed printable-assist features can remain on the final substrate/wafer and be supported by, e.g., single photo/etch flow as well as double pattern flows where etching other assist feature (e.g., ghost poly) may damage adjacent active silicon in its second etch.

The printable-assist features can provide many advantages. For example, the layout rules can be directly used by design to represent the best lithographic process control of critical transistors. These layout rules can encompass basic lithography principles (e.g., in a grid format) that do not need to be explicitly understood by designers. All designated critical gates can be inherently shielded using these printable assist features by a single photo/etch process, and, alternatively by a double pattern process. Additionally, the printable assist features can be optimized to meet process requirement (e.g., size ups/area rules) after the design layout to provide process/OPC teams flexibility, as compared with other solutions in the prior art, which typically provide support of a few transistor cases post layout.

Off-axis illumination (OAI), for example, using a monopole element, a dipole element, a quadrupole element, etc., is typically required to illuminate critical layers for advanced technology nodes to achieve tight pitch requirements. OAI works well when illuminating a plurality of elongated, parallel structures such as a transistor gate array or interconnect lines. However, such illuminators generally are less successful at patterning “L” shaped structures, and margins are particularly poor when imaging “S” shaped structures having two angles of 90°. These shaped structures are critical for scaling die area to form, for example, transistor gate layers and metal layers.

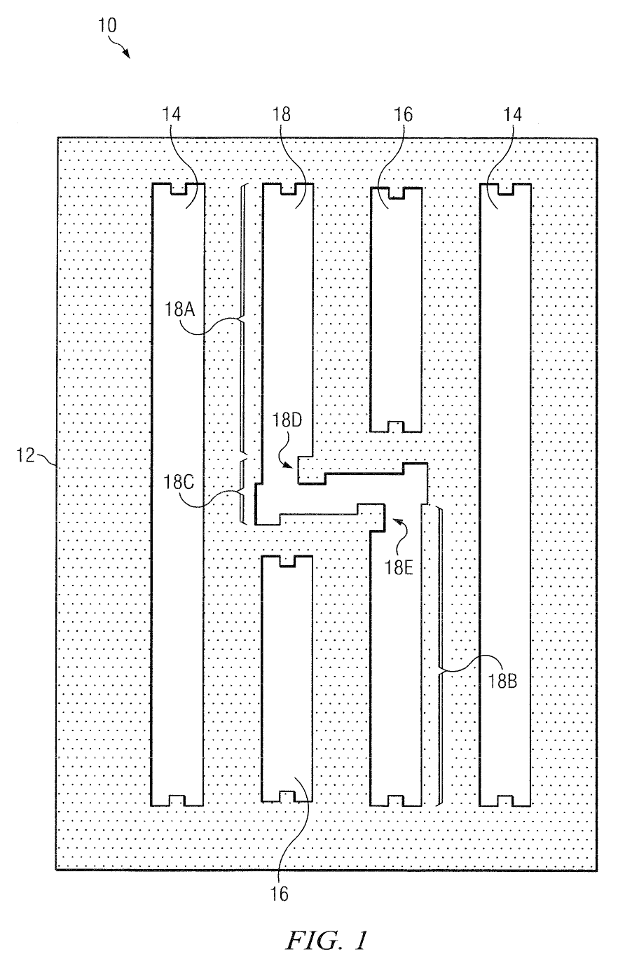

FIG. 1 depicts a portion of a photomask or reticle 10 (hereinafter, collectively, “mask”) which can be illuminated with a light source which has been shaped using off-axis illumination. The photomask 10 can include a background 12, first patterned areas 14, second patterned areas 16, and one or more third patterned areas 18. It will be appreciated that the background 12 can be opaque and the patterned areas 14-18 can be transparent, or these opaque and transparent areas can be reversed. Further, the photomask 10 can include semi-transparent areas which can be a part of the background 12, part of the patterned areas 14-18, separate patterned areas, or more than one of these. Other features may be formed on the mask, such as print-assist features.

First patterned areas 14 and second patterned areas 16 are elongated, parallel structures which can be reproduced within a photosensitive layer with high accuracy using OAI. The shape of the third patterned area 18, however, is less accurately reproduced within the photosensitive layer. The third area 18 includes a first segment 18A aligned along an axis, a second segment 18B aligned along an axis which is generally parallel with segment 18A, and segment 18C which is aligned along an axis which is oriented generally perpendicular to (i.e., forming right angles with) the orientations of segments 18A and 18B. Feature 18 further includes a first inside angle 18D (i.e., the smaller angle at a turn point of a line, or the smaller angle at a point of intersection of two intersecting line segments) of 90° and a second inside angle 18E of 90° which are used to route the patterned feature between locations on a semiconductor wafer or semiconductor die.

Because the third patterned area 18 includes two inside angles 18D, 18E of 90°, the use of off-axis illumination elements such as monopole, dipole, and quadrupole elements is less effective in accurately reproducing the feature 18 in a photosensitive layer compared with features 14, 16. Because the photosensitive layer is less accurately patterned, a layer patterned by the photosensitive layer will also be less accurately reproduced.

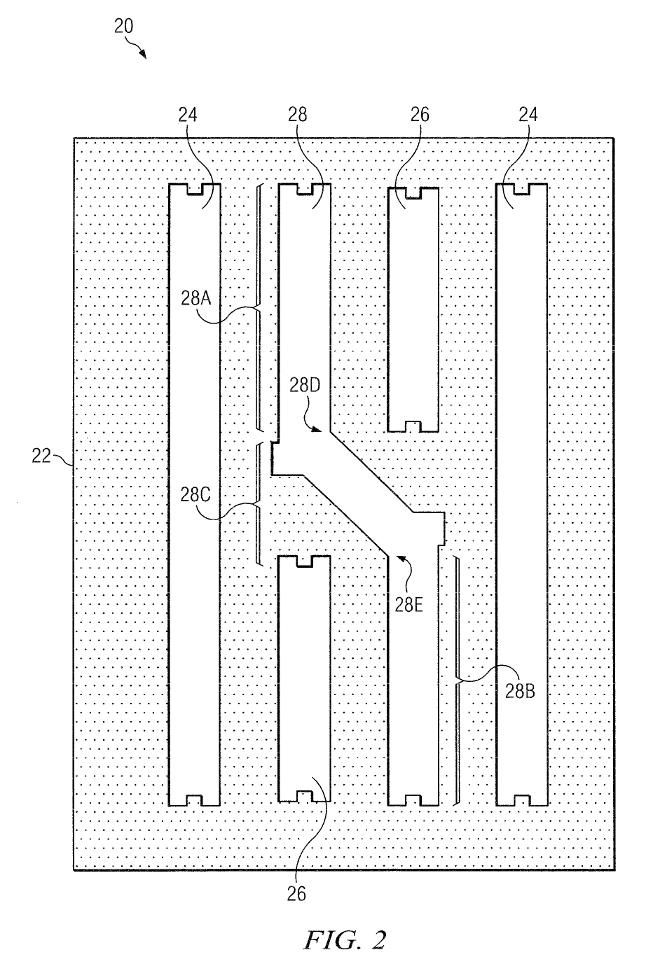

FIG. 2 depicts an embodiment of the present teachings, which can include a portion of a mask 20. The mask 20 can include a background 22, first patterned areas 24, second patterned areas 26, and one or more third patterned areas 28 which can be a continuous patterned line. It will be appreciated that the background 22 can be opaque and the patterned areas 14-18 can be transparent, or the opaque and transparent areas can be reversed. Further, the photomask 20 can include semi-transparent areas which can be a part of the background 22, part of the patterned areas 24-28, separate patterned areas, or a combination. Other features may be formed on the mask, such as print-assist features.

First patterned areas 24 and second patterned areas 26 are elongated, parallel structures which can be reproduced within a photosensitive layer with high accuracy using OAI. The patterned line 28 in the design of mask 20 includes a first line segment 28A aligned along an axis, a line segment 28B aligned along an axis which is generally parallel with line segment 28A, and a third line segment 28C which connects the first line segment 28A to the second line segment 28B, and which is aligned along an axis which is oriented at an oblique angle relative to the orientations of line segments 28A and 28B. The line segments 28A-28C are continuous to provide a continuous patterned line 28. In the embodiment of FIG. 2, the axis of line segment 28C is oriented diagonally at a 45° angle with respect to the axes of line segments 28A and 28B. Line 28 further includes a first inside angle 28D of 135° and a second inside angle 28E of which are used to route the patterned feature between locations on a semiconductor wafer or semiconductor die.

Third patterned area 28 includes two inside angles 28D, 28E which are more open (i.e., larger) than 90°, and the use of OAI is more effective in accurately reproducing the pattern feature in a photosensitive layer, and within a layer patterned by the photosensitive layer. It will be appreciated that the outside angles (i.e., the larger angle at a turn point of a line) of third patterned area 28 are less than 270°, while the outside angles of the third area 18 of FIG. 1 are 270°.

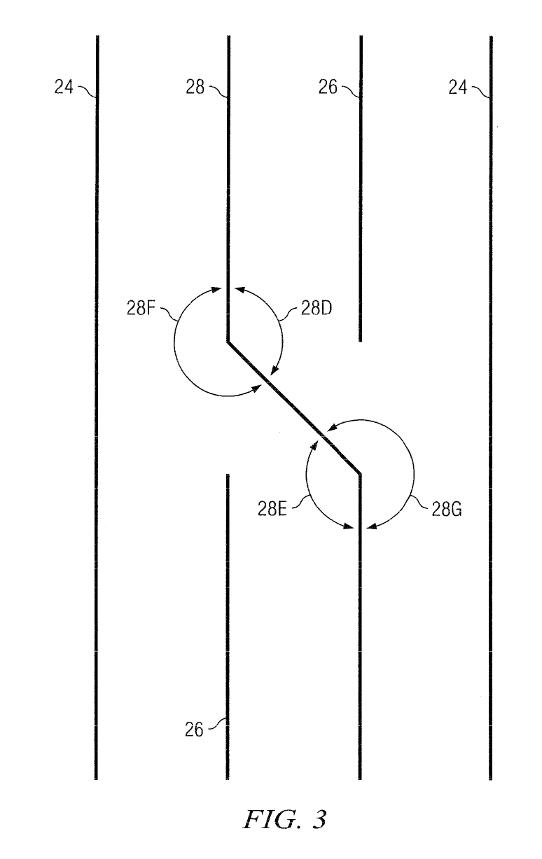

FIG. 3 depicts various axes of the first patterned areas 24 and the second patterned areas 26, and various axes and angles of the third patterned area 28 of FIG. 2. FIG. 3 includes first inside angle 28D, second inside angle 28E, first outside angle 28F, and second outside angle 28G. In the embodiment depicted, angles 28D and 28G are both 135° and angles 28F and 28G are both 225°. It is contemplated, however, that other angles would also increase the effectiveness of off-axis illumination. For example, in another embodiment, the two inside angles can be greater than 90° and less than 180°, with the two outside angles being less than 270° and greater than 180°. In another embodiment, the two inside angles can range from about 120° to about 150° (i.e., an angle of between about 30° and about 60° with respect to the axes of features 24), with the two outside angles ranging from about 240° to about 210°. In another embodiment, the two inside angles can range from about 120° to about 135° (i.e., an angle of between about 30° and about 45° with respect to the axes of features 24), with the two outside angles ranging from about 240° to about 225°.

Embodiments of the present teachings can be particularly suited for technology nodes of 30 nm to 40 nm or less, which use a printed feature of about 50 nm to 60 nm wide to etch a feature having a final width of about 30 nm to 40 nm. That is, a line feature formed using a technology node of 30 nm can print a feature which is about 50 nm wide within a resist layer, and can form a feature which is about 30 nm wide once it has been etched using the 50 nm wide printed resist layer. In other words, the technology node refers to a minimum feature size which can be formed with the specified technology node. With technology nodes of 30 nm to 40 nm or less, the use of OAI more accurately produces the mask feature within a photosensitive layer. More accurate reproduction of the mask features in a photosensitive layer can result in improved process margins and reduced production costs.

A mask in accordance with the present teachings can have intersecting line segments in which an inside angle formed by two or more intersecting line segments is greater than 90° and an outside angle formed by the two or more intersecting line segments is less than 270°. In another embodiment, all intersecting line segments form inside angles of greater than 90° and outside angles less than 270°, with no intersecting line segments being outside these ranges. In yet another embodiment, a mask in accordance with the present teachings can have intersecting line segments in which an inside angle formed by two or more intersecting line segments is in the range of 120° and 150° and an outside angle formed by the two or more intersecting line segments is in the range of 240° and 210°. In still another embodiment, all intersecting line segments form inside angles in the range of 120° and 150° and outside angles in the range of 240° and 210°, with no intersecting line segments being outside these ranges.

Illuminating a mask in accordance with the present teachings, particularly using an illumination source which has been shaped using an OAI element, can result in a device feature which more accurately matches the mask feature used to pattern the feature.

It can be seen that a minimum distance between second patterned areas 26 and third patterned area 28 in FIG. 2 is greater than a minimum distance between second patterned areas 16 and third patterned area 18 in FIG. 1. The spacing of FIG. 1 can be maintained in FIG. 2, for example, by moving second patterned areas 26 closer to third patterned area 28. This can reduce the area (i.e., “real estate”) used by the structure of FIG. 2 compared to the structure of FIG. 1, while providing a similar functionality. That is, the FIG. 2 structure can be formed more densely than the FIG. 1 structure while providing a similar functionality. Thus an embodiment of the present teachings can be used to form more structures per unit area than the FIG. 1 structure.

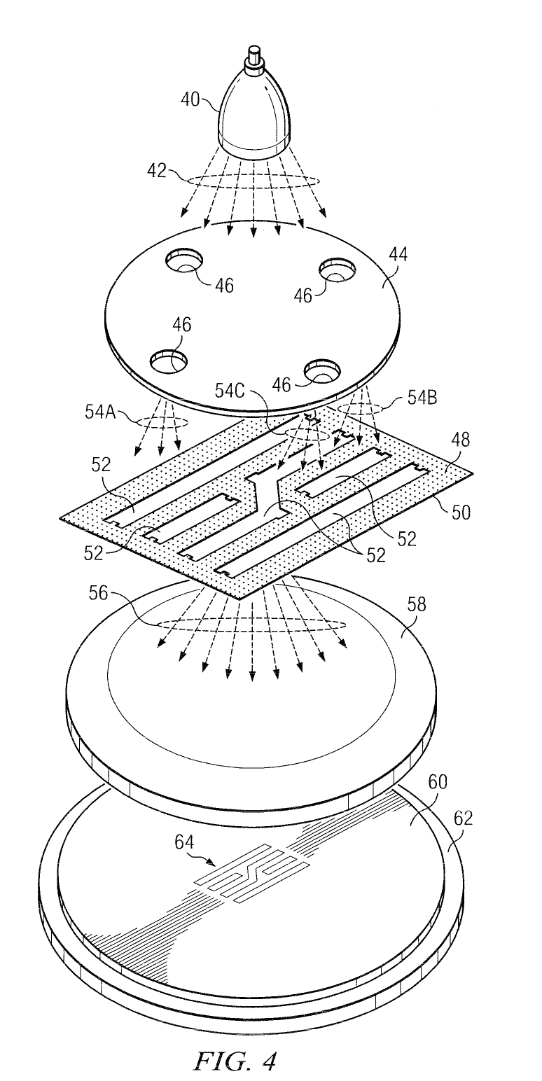

FIG. 4 depicts photolithographic equipment in accordance with another embodiment of the present teachings. FIG. 4 depicts a scanner including an illumination source (light source) 40 outputting a first intensity of light 42 at a wavelength (λ). The light can be either within the visible spectrum, outside the visible spectrum (for example, ultraviolet, infrared, x-ray, etc.), or contain both visible and invisible elements. An off-axis illumination element 44 is interposed between the light source 40 and a mask 48. In this embodiment, the OAI element 44 is depicted as a quadrupole element including four openings 46 therethrough, but it will be appreciated that other OAI elements, such as a monopole element, a dipole element, etc., may be used. The mask 48 can include a background 50 and at least one patterned area 52 in accordance with the mask embodiments discussed above. A second intensity of light including 54A, 54B, 54C (and 54D, not depicted in the perspective view of FIG. 4) passes through, and is shaped by, openings 46 in the OAI element 44 to illuminate mask 48.

A third intensity of light 56 passes through, and is patterned by, the openings in the mask 48. At least a portion of the third intensity of light 56 enters an optical lens or series of lenses 58 having a numerical aperture, where the light is focused onto a photosensitive layer 60, such as a layer of resist covering a semiconductor wafer 62. The light 56 focused by the lens 58 illuminates the resist layer 60 and provides an image 64 which is reproduced in miniature from the pattern in mask 48 onto the resist layer 60.

After exposing the photoresist using the orientation of the OAI element as depicted in FIG. 4, the OAI element 44 can be rotated to provide a second illumination of the mask and a second exposure of the resist layer. For example, in the case of a dipole element, the element can be rotated by 90°, then the resist 60 is exposed again. The use of the OAI element provides for a more faithful reproduction of the mask pattern 26 onto the photoresist layer 60 in conjunction with the mask formed according to the present teachings. A system such as that depicted in FIG. 4 including the mask 48 as described above with reference to FIGS. 2 and 3 can improve the image 64 and provide a structure within a smaller area over a system using a conventional mask layout.

In an embodiment of the present teachings, the features which are formed can include the inside and outside angles as discussed above. The CD's of these features can be of a size which is less than the wavelength of the illumination source divided by the numerical aperture of the scanner lens (i.e. CD<λ/NA). In another embodiment, the inside and outside angles discussed above can occur between line ends (i.e. line end geometry) as depicted, for example, in FIG. 2. In yet another embodiment, the features can be formed to a size such that CD<λ/NA, and also at a location between line ends. The methods discussed above provide for the formation of structures having these size and shape characteristics.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g., −1, −2, −3, −10, −20, −30, etc.

While the present teachings have been illustrated with respect to one or more implementations, alterations and/or modifications can be made to the illustrated examples without departing from the spirit and scope of the appended claims. In addition, while a particular feature of the disclosure may have been described with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A method for imaging a pattern onto a photosensitive layer, comprising:
providing an emitted light from a light source;
passing at least a portion of the emitted light through an off-axis illumination (OAI) element to shape the emitted light;
passing at least a portion of the shaped emitted light through a patterned mask comprising at least one continuous patterned line to pattern the shaped emitted light, wherein the continuous patterned line comprises:
a first line segment aligned along a first axis of orientation;
a second line segment aligned along a second axis of orientation which is generally parallel to the first axis of orientation; and
a third line segment aligned along a third axis of orientation which is oriented at an oblique angle relative to the first axis of orientation and the second axis of orientation, wherein the third line segment connects the first line segment to the second line segment; and
illuminating a photosensitive layer with the patterned shaped emitted light.

2. The method of claim 1, further comprising passing at least a portion of the shaped emitted light through the patterned mask, wherein:
the third line segment forms a first inside angle of greater than 90° with the first line segment and a first outside angle of less than 270° with the first line segment; and
the third line segment forms a second inside angle of greater than 90° with the second line segment and a second outside angle of less than 270° with the second line segment.

3. The method of claim 1, further comprising passing the at least a portion of the shaped emitted light through the patterned mask, wherein:
the third line segment forms a first inside angle in the range of about 120° to about 150° with the first line segment and a first outside angle in the range of about 240° to about 210° with the first line segment; and
the third line segment forms a second inside angle in the range of about 120° to about 150° with the second line segment and a second outside angle in the range of about 240° to about 210° with the second line segment.

4. The method of claim 1, further comprising:
forming a line segment within the photosensitive layer, wherein the line segment formed within the photosensitive layer has a width of 60 nm or less.

5. The method of claim 1, further comprising:
passing at least a portion of the shaped emitted light through the patterned mask, wherein:
the patterned mask comprises a plurality of patterned intersecting lines to pattern the light; and
each intersection of the intersecting lines of the patterned mask forms an inside angle of greater than 90° and an outside angle of less than 270°.

6. The method of claim 1, further comprising:
passing at least a portion of the shaped emitted light through the patterned mask, wherein:
the pattern mask comprises a plurality of patterned intersecting lines to pattern the light; and
each intersection of the intersecting lines of the patterned mask forms an inside angle in the range of about 120° and 150° and an outside angle in the range of 240° and 210°.

7. The method of claim 1, further comprising:
passing at least a portion of the patterned shaped emitted light through at least one lens; and
the illumination of the photosensitive layer with the patterned shaped emitted light exposes the photosensitive layer with a pattern having a line width which is less than a wavelength of the emitted light divided by a numerical aperture of the at least one lens.

8. The method of claim 7, further comprising:
the first line segment comprises a first line end; and
the second line segment comprises a second line end.

9. A patterned mask for imaging a photosensitive layer, comprising:
a continuous patterned line, comprising:
a first line segment aligned along a first axis of orientation;
a second line segment aligned along a second axis of orientation which is generally parallel to the first axis of orientation; and
a third line segment aligned along a third axis of orientation which is oriented at an oblique angle relative to the first axis of orientation and the second axis of orientation, wherein the third line segment connects the first line segment to the second line segment.

10. The patterned mask of claim 9, wherein the continuous patterned line further comprises:
a first point of intersection of the first line segment and the third line segment has a first inside angle of greater than 90° and a first outside angle of less than 270°; and
a second point of intersection of the second line segment and the third line segment has a second inside angle of greater than 90° and a second outside angle of less than 270°.

11. The patterned mask of claim 9, wherein the continuous patterned line further comprises:
a first point of intersection of the first line segment and the third line has a first inside angle in the range of about 120° to about 150° and a first outside angle in the range of about 240° to about 210°; and
a second point of intersection of the second line segment and the third line segment has a second inside angle in the range of about 120° to about 150° and a second outside angle in the range of about 240° to about 210°.

12. The patterned mask of claim 9, wherein:
the patterned mask is adapted to image a line segment having a width of 60 nm or less within a photosensitive layer.

13. The patterned mask of claim 9, further comprising:
a plurality of continuous patterned lines each comprising at least three line segments and at least two line segment intersections, wherein each of the at least two line segment intersections of each of the plurality of continuous patterned lines of the patterned mask form an inside angle of greater than 90° and an outside angle of less than 270°.

14. The patterned mask of claim 9, further comprising:
a plurality of continuous patterned lines each comprising at least three line segments and at least two line segment intersections, wherein each of the at least two line segment intersections of each of the plurality of continuous patterned lines of the patterned mask form an inside angle in the range of about 120° and 150° and an outside angle in the range of 240° and 210°.

15. A method for imaging a pattern during the formation of a semiconductor device, comprising:
forming a photosensitive layer over a semiconductor wafer or semiconductor wafer section;
providing an emitted light from a light source;
passing at least a portion of the emitted light through an off-axis illumination (OAI) element to shape the emitted light;
passing at least a portion of the shaped emitted light through a patterned mask comprising at least one continuous patterned line to pattern the shaped emitted light, wherein the continuous patterned line comprises:
a first line segment aligned along a first axis of orientation;
a second line segment aligned along a second axis of orientation which is generally parallel to the first axis of orientation; and
a third line segment aligned along a third axis of orientation which is oriented at an oblique angle relative to the first axis of orientation and the second axis of orientation, wherein the third line segment connects the first line segment to the second line segment; and
illuminating the photosensitive layer with the patterned shaped emitted light.

16. The method of claim 15, further comprising passing at least a portion of the shaped emitted light through the patterned mask, wherein:
the third line segment forms a first inside angle of greater than 90° with the first line segment and a first outside angle of less than 270° with the first line segment; and
the third line segment forms a second inside angle of greater than 90° with the second line segment and a second outside angle of less than 270° with the second line segment.

17. The method of claim 15, further comprising passing the at least a portion of the shaped emitted light through the patterned mask, wherein:
the third line segment forms a first inside angle in the range of about 120° to about 150° with the first line segment and a first outside angle in the range of about 240° to about 210° with the first line segment; and
the third line segment forms a second inside angle in the range of about 120° to about 150° with the second line segment and a second outside angle in the range of about 240° to about 210° with the second line segment.

18. The method of claim 15, further comprising:
forming a line segment within the photosensitive layer, wherein the line segment formed within the photosensitive layer has a width of 60 nm or less.

19. The method of claim 15, further comprising:
passing at least a portion of the shaped emitted light through the patterned mask, wherein:
the patterned mask comprises a plurality of patterned intersecting lines to pattern the light; and
each intersection of the intersecting lines of the patterned mask forms an inside angle of greater than 90° and an outside angle of less than 270°.

20. The method of claim 15, further comprising:
passing at least a portion of the shaped emitted light through the patterned mask, wherein:
the pattern mask comprises a plurality of patterned intersecting lines to pattern the light; and
each intersection of the intersecting lines of the patterned mask forms an inside angle in the range of about 120° and 150° and an outside angle in the range of 240° and 210°.
